(19) United States
(12) Patent Application Publication
(10) Pub. No.: US 2023/0318341 A1
(43) Pub. Date: Oct. 5, 2023

(54) CAPACITOR DISCHARGE TOOL

(71) Applicant: Schweitzer Engineering Laboratories, Inc., Pullman, WA (US)

(72) Inventors: Kevin R. Rogerson, Colton, WA (US); Anthony L. Zarate, Stanwood, WA (US); Johnathan A. Hubert, Romeny, IN (US)

(73) Assignee: Schweitzer Engineering Laboratories, Inc., Pullman, WA (US)

(21) Appl. No.: 17/711,216

(22) Filed: Apr. 1, 2022

(51) Int. Cl. H02J 7/00; H02J 7/34

(52) U.S. Cl. CPC H02J 7/00712; H02J 7/0047; H02J 7/0013; H02J 7/345

(57) ABSTRACT

An active capacitor discharge tool may include circuitry for efficiently discharging a capacitor. The active capacitor discharge tool may include batteries (or regulated voltage sources) for actively discharging a capacitor using multiple discharge paths. The active capacitor discharge tool may alternatively short the capacitor to a ground connection using the multiple discharge paths based on a timing associated with a clock frequency of a clock signal. Discharging a capacitor by alternatively grounding the capacitor using different discharge paths may distribute a generated discharging heat and may discharge the capacitor faster. Moreover, when a capacitor includes stored electrical charges corresponding to a capacitor voltage lower than a sufficiently discharged voltage to enable an operator to handle the capacitor, the active capacitor discharge tool may short an anode and a cathode of the capacitor to discharge the capacitor to the ground connection voltage level.

### BACKGROUND FIELD

The present disclosure relates generally to systems and methods for discharging a capacitor and, more particularly, to a device for discharging a wide range of electrical energy stored in a capacitor.

Capacitors store electrical energy that may be provided to certain electrical equipment to perform a function. For example, one or multiple capacitors may provide stored electrical energy to a switch to open or close a transmission line of an electric power distribution system. Operators may occasionally perform maintenance or other operations on electrical equipment associated with these capacitors. An operator may first discharge a capacitor before handling, assembling, or replacing the capacitor. Many devices for discharging the capacitor, however, could take an excessive amount of time accessing the capacitor or produce excessive heat.

### BRIEF DESCRIPTION OF THE DRAWINGS

Non-limiting and non-exhaustive embodiments of the disclosure are described herein, including various embodiments of the disclosure with reference to the figures listed below.

FIG. 1 depicts an active capacitor discharge tool for discharging a capacitor, in accordance with an embodiment;

FIG. 2 depicts a block diagram associated with the circuitry of the active capacitor discharge tool of FIG. 1, in accordance with an embodiment;

FIG. 3 depicts an example schematic associated with a discharge circuit and a portion of a logic circuit of FIG. 2, in accordance with an embodiment;

FIG. 4 depicts another portion of the logic circuit providing the activation signals to the discharge circuit and the portion of the logic circuit described in FIG. 3, in accordance with an embodiment; and

FIG. 5 depicts an operating process associated with the active capacitor discharge tool, in accordance with an embodiment.

### DETAILED DESCRIPTION

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “some embodiments,” “embodiments,” “one embodiment,” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

Systems and methods are described herein for discharging a capacitor. A capacitor discharge tool may discharge a wide range of electrical energy (or accumulated electrical charge) stored in the capacitor. For example, an electric power distribution system may include one or multiple capacitors for providing the stored electrical energy to perform a function (e.g., opening or closing a re-closer, switching a state of a component, etc.). Moreover, different capacitors may include different capacity for storing electrical charges. Indeed, some capacitors may only be handled after they have been discharged. That said, even some discharged (or partially discharged) capacitors may accumulate undesired electrical charges, such as static charges, due to a dielectric absorption property of the capacitors. For example, some capacitors may accumulate electrical charges up to 10% of a respective electrical charge capacity in a short period of time (e.g., a few minutes, few hours, and so on). Such accumulated electrical charges may be undesired. In some cases, the accumulated electrical charges could damage a circuit board or cause other problems. As such, the operator may discharge the capacitor before handling, assembling, and/or placing the capacitor.

To rapidly discharge a capacitor without generating excessive heat, an operator may use the capacitor discharge tool of this disclosure to discharge the capacitor. The capacitor discharge tool may electrically couple to the leads (e.g., positive and negative leads, cathode and anode) of the capacitor. A passive capacitor discharge tool may passively discharge the capacitor by grounding the capacitor. For example, a passive capacitor discharge tool may ground the capacitor such that a voltage of the capacitor may passively drop to a ground voltage (e.g., 0 volts (V)) or near ground voltage (e.g., near 0V).

To prevent some of the challenges that may arise from using a passive capacitor discharge tool (e.g., generating excessive heat, taking an excessively long time to discharge a capacitor), this disclosure describes an active capacitor discharge tool that may actively discharge the capacitor by actively switching between multiple discharge paths for grounding the capacitor. For example, actively switching between the multiple discharge paths may include alternatingly opening and closing different discharge paths to ground the capacitor. Actively switching between the multiple discharge paths may distribute heat (e.g., circuit temperature) caused by discharging the electrical charges of the capacitor. As such, actively switching between the multiple discharge paths may allow for a capacitor to be discharged faster while reducing localized heat caused by the discharge of electricity from the capacitor.

A lower circuit heat and using multiple discharge paths may accelerate the capacitor discharging process. The active capacitor discharge tool may carry out a switching scheme for actively switching between two or more discharge paths for grounding the capacitor. In some cases, the switching scheme may actively open and close a number of discharge paths to ground the capacitor based on a clock signal.

For example, the switching scheme may alternatingly open and close two or more discharge paths based on a clock signal (e.g., high and low values of the clock signal). Additionally or alternatively, the switching scheme may also alternatingly open and close the two or more discharge paths based on a counter value associated with the clock signal, a timer associated with the clock signal, or any other viable timing scheme. In such cases, the active capacitor discharge tool may discharge the capacitor faster while reducing a probability of overheating the discharging circuitry. Although the terms capacitor and capacitor discharge tools are used herein, it should be appreciated that the described systems, devices, or methods may be used for any component (e.g., electrical component) that may hold (e.g., accumulate) electrical charges.

In some cases, actively discharging the capacitor using the two or more discharge paths may discharge the capacitor to a lower charge and/or voltage level compared to passively grounding the capacitor. For example, the active capacitor discharge tool may short the capacitor leads when detecting a low voltage. The active capacitor discharge tool may actively monitor a voltage of the capacitor for detecting the low voltage. In some cases, the active capacitor discharge tool may include a voltage comparator for actively monitoring the voltage of the capacitor to short the capacitor leads. As such, the active capacitor discharge tool may discharge the capacitor to a lower charge and/or voltage level (e.g., ground voltage, 0V) compared to passively grounding the capacitor.

With the foregoing in mind, the active capacitor discharge tool may reduce a probability of electrical shocks, burns, or injuries of the operator based at least in part on a faster discharging time of a capacitor, a lower circuit heat generation when discharging the capacitor, and lower charge and/or voltage level when the capacitor is discharged. Moreover, the active capacitor discharge tool may also reduce a probability of damaging a circuit board, causing a spark or other possibilities, by discharging the capacitor to a lower charge level and/or voltage.

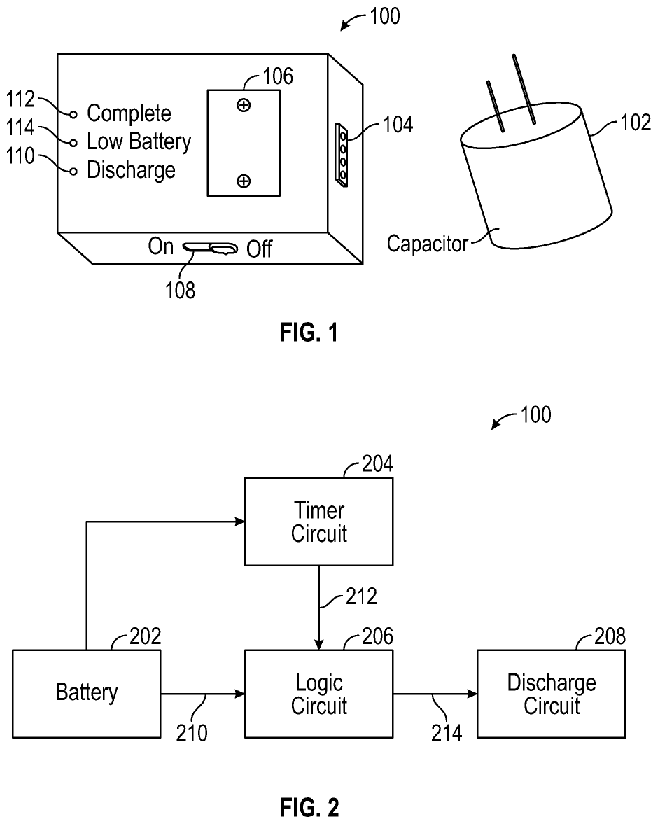

FIG. 1 depicts an active capacitor discharge tool 100 for discharging a capacitor 102. In the depicted embodiment, the active capacitor discharge tool 100 may include a connector 104, a battery storage 106, a power switch 108, a discharge led indicator 110, a complete LED indicator 112 to indicate a completed discharge process, and a low battery LED indicator 114. However, in different embodiments, the active capacitor discharge tool 100 may include different components, parts, and/or different arrangement of components. For example, in alternative or additional embodiments, the active capacitor discharge tool 100 may include a button in lieu of the power switch 108.

The connector 104 may electrically connect to leads of the capacitor 102. In different embodiments, the connector 104 may include a plug, a socket, or any other viable interface connector. For example, an operator may couple the active capacitor discharge tool 100 to the capacitor 102 via the connector 104. Accordingly, the connector 104 may electrically connect the capacitor 102 with circuitry disposed inside the active capacitor discharge tool 100 to discharge the capacitor 102, as will be appreciated.

In some cases, the battery storage 106 may provide a housing for one or more batteries to provide a regulated voltage to the circuitry disposed inside the active capacitor discharge tool 100. The one or more batteries may provide electrical power for actively discharging the capacitor 102. For example, the one or more batteries may alternatively activate switches (e.g., FET switches) to close (or short) two or more discharge paths of the circuitry disposed inside the active capacitor discharge tool 100 to discharge the capacitor 102. In specific cases, alternatively activating the switches may include an overlapping period when at least two of the discharge paths are closed (or shorted) simultaneously. In such cases, the at least two of the discharge paths that are closed simultaneously may both discharge the capacitor 102 during the overlapping period. Alternatively or additionally, alternatively activating the switches may cause one of the two or more discharge paths to discharge the capacitor 102 at each time. Moreover, in different embodiments, the active capacitor discharge tool 100 may use different types of batteries. As such, in different embodiments, the battery storage 106 may include a housing for a respective battery type.

For example, the active capacitor discharge tool 100 may use electrical power provided by non-rechargeable batteries or rechargeable batteries. In some cases, the active capacitor discharge tool 100 may recharge the rechargeable batteries using the stored charges (or stored electrical power) of the capacitor 102 when using the rechargeable batteries. In any case, the battery storage 106 may provide a housing for an electric power source for actively discharging the capacitor 102.

That said, in alternative or additional embodiments, the active capacitor discharge tool 100 may include a voltage regulator for providing the regulated voltage to the circuitry disposed inside the active capacitor discharge tool 100. For example, the voltage regulator may receive an unregulated voltage or high voltage and provide the regulated voltage to the circuitry disposed inside the active capacitor discharge tool 100. The active capacitor discharge tool may include one or more batteries, one or more voltage regulators, or both.

The power switch 108 may turn on and off the active capacitor discharge tool 100. In some cases, the operator may use the power switch 108 to turn on and off the active capacitor discharge tool 100. In alternative or additional cases, the power switch 108 may include a button for turning on and off the active capacitor discharge tool 100. Moreover, in yet alternative or additional embodiments, the active capacitor discharge tool 100 may include automatic switching circuitry for discharging the capacitor 102. For example, such automatic switching circuitry may turn on the active capacitor discharge tool 100 to discharge the electrical charges of the capacitor 102 upon detecting a voltage higher than a threshold.

When the power switch 108 is in off position, the circuitry disposed inside the active capacitor discharge tool 100 may not discharge the capacitor 102. For example, the operator may couple the active capacitor discharge tool 100 to the capacitor 102 when the power switch 108 is in an off position. Moreover, when the power switch 108 is in an on position, the active capacitor discharge tool 100 may discharge the electrical charges stored in the capacitor 102.

The active capacitor discharge tool 100 may include a discharge circuit and a timer circuit. The timer circuit may provide the clock signal to the discharge circuit to actively discharge the capacitor 102 via two or more discharge paths. In some cases, the active capacitor discharge tool 100 may alternatively open and close the two or more discharge paths based on high and low values of a clock signal. In some cases, when the power switch 108 is in off position, the timer circuit may not provide the clock signal to the discharge circuit. Accordingly, the two or more discharge paths may be open when the power switch 108 is in off position. As mentioned above, in specific cases, alternatively opening and closing the two or more discharge paths may include overlapping periods when at least two of the two or more discharge paths may actively discharge the capacitor 102.

The discharge led indicator 110, the complete LED indicator 112, and the low battery LED indicator 114 may provide different visual indications to the operator. The discharge led indicator 110 may provide an indication of high charge and/or voltage levels of the capacitor 102. For example, the active capacitor discharge tool 100 may include comparator circuitry (e.g., one or multiple comparator circuits) to detect whether the voltage of the capacitor 102 is above a threshold (e.g., above a sufficiently discharged voltage threshold, above 5V, 4V, 3V, 2.5V, 2.2V, 2.0V, 1.8V, 1.6V, 1.4V, 1.2V, 1.0V, etc.). Accordingly, the operator may be informed of a possibility of electrical shock when the discharge led indicator 110 is on. Moreover, the discharge led indicator 110 may provide the indication of high charge and/or voltage levels of the capacitor 102 when the active capacitor discharge tool 100 is discharging the capacitor 102. In one example, the discharge led indicator 110 may include a red LED.

The complete LED indicator 112 may provide an indication of low charge and/or voltage levels of the capacitor 102 to the operator. For example, the complete LED indicator 112 may indicate when the operator may handle (e.g., touch) the capacitor. The complete LED indicator 112 may provide the indication when the voltage of the capacitor is below a threshold (e.g., below the sufficiently discharged voltage threshold, below 5V, 4V, 3V, 2.5V, 2.2V, 2.0V, 1.8V, 1.6V, 1.4V, 1.2V, 1.0V, etc.). In some cases, the active capacitor discharge tool 100 may use the comparator circuitry to detect whether the voltage of the capacitor 102 is below the threshold. Accordingly, the operator may be informed when the capacitor 102 is discharged to a sufficiently low charge and/or voltage level when the complete LED indicator 112 is on. In one example, the complete LED indicator 112 may include a green LED.

The low battery LED indicator 114 may provide an indication of low battery level of the one or more batteries. For example, the active capacitor discharge tool 100 may use the comparator circuitry to determine whether the battery level of the one or more batteries disposed in the battery storage 106 are below a battery voltage threshold. In some cases, the active capacitor discharge tool 100 may not close (or timely close) the discharge paths for grounding the capacitor 102 when having low battery levels. Accordingly, the active capacitor discharge tool 100 may not discharge the capacitor 102 or may take longer time to discharge the capacitor 102.

Moreover, in some cases, to prevent the active capacitor discharge tool 100 from providing an erroneous indication of sufficiently low charge and/or voltage level by turning on the complete LED indicator 112 when having low battery levels, the operator may be informed that the active capacitor discharge tool 100 when the low battery LED indicator 114 is on. In one example, the low battery LED indicator 114 may include a yellow LED.

FIG. 2 depicts a block diagram of the active capacitor discharge tool 100. The active capacitor discharge tool 100 may include a battery 202, a timer circuit 204, a logic circuit 206, and a discharge circuit 208. That said, it should be appreciated that in alternative or additional embodiments, the active capacitor discharge tool 100 may include alternative or additional circuitry for actively discharging the capacitor 102. Moreover, although the embodiments below are described with respect to discharging the capacitor 102, the active capacitor discharge tool 100 may also discharge electrical charges or voltage of other components.

The battery 202 may include one or more batteries and a voltage regulator, or any viable source of electrical power (e.g., an input to receive alternating current (AC) power, an input to receive power discharged from the capacitor 102 itself). In the depicted embodiment, the battery 202 may provide a regulated voltage signal 210 to the timer circuit 204 and the logic circuit 206. The timer circuit 204 may include a clock oscillator component or any other viable circuitry to provide a clock signal 212 (e.g., an oscillating signal). The clock signal 212 may oscillate between high and low values at a clock frequency. The timer circuit 204 may provide the clock signal 212 to the logic circuit 206. The logic circuit 206 may use the clock signal 212 to provide activation signals 214, as will be appreciated.

The logic circuit 206 may receive the regulated voltage signal 210 and the clock signal 212. Moreover, the logic circuit 206 may electrically connect to the capacitor 102 via the connector 104 described above. The logic circuit 206 may include comparator circuitry for monitoring a voltage level of the regulated voltage signal 210 and the voltage level (or charge level) of the capacitor 102. For example, the logic circuit 206 may turn on the discharge led indicator 110 when the capacitor voltage level is above a threshold (e.g., above the sufficiently discharged voltage level, above 5V, 4V, 3V, 2.5V, 2.2V, 2.0V, 1.8V, 1.6V, 1.4V, 1.2V, 1.0V, etc.). Moreover, the logic circuit 206 may turn on the complete LED indicator 112 when the capacitor voltage level is equal to or below the threshold. Furthermore, the logic circuit 206 may turn on the low battery LED indicator 114 when the regulated voltage signal 210 is below a battery voltage threshold.

The discharge circuit 208 may electrically connect to the capacitor 102 via the connector 104. The logic circuit 206 may provide the activation signals 214 to the discharge circuit 208 for actively discharging the capacitor 102 via the two or more discharge paths, as will be appreciated. The logic circuit 206 may provide the activation signals 214 based on the clock signal 212 to alternatively open and close the two or more discharge paths. In some cases, the logic circuit 206 may provide the clock signal 212 to a first discharge path of the discharge circuit 208 and provide an inverted clock signal 212 to a second discharge path of the discharge circuit 208. For example, the discharge circuit 208 may close the first discharge path in response to a high clock signal 212 and may close the second discharge path in response to a low clock signal 212, based on receiving the inverted clock signal 212. Moreover, the discharge circuit 208 may distribute a heat generated based on discharging the capacitor 102 over the first discharge path and the second discharge path.

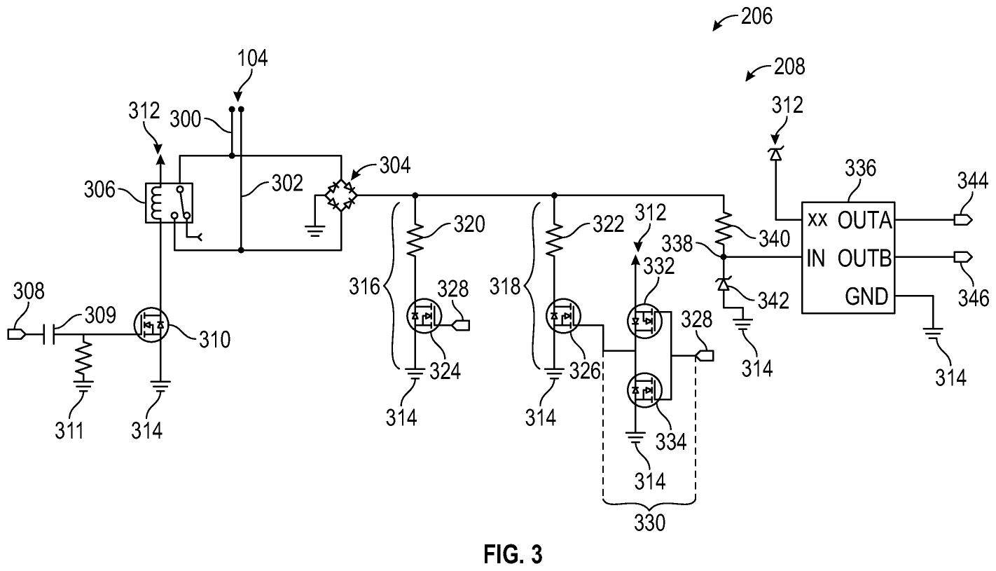

FIG. 3 depicts an example schematic associated with the discharge circuit 208 and a portion of the logic circuit 206. As mentioned above, the discharge circuit 208 may connect to the capacitor 102 via the connector 104. The connector 104 may include a plug, a socket, or any other viable interface connector to connect to the capacitor 102. That said, a first electrical path 300 may connect to a positive lead of the capacitor 102 and a second electrical path 302 may connect to a negative lead of the capacitor 102.

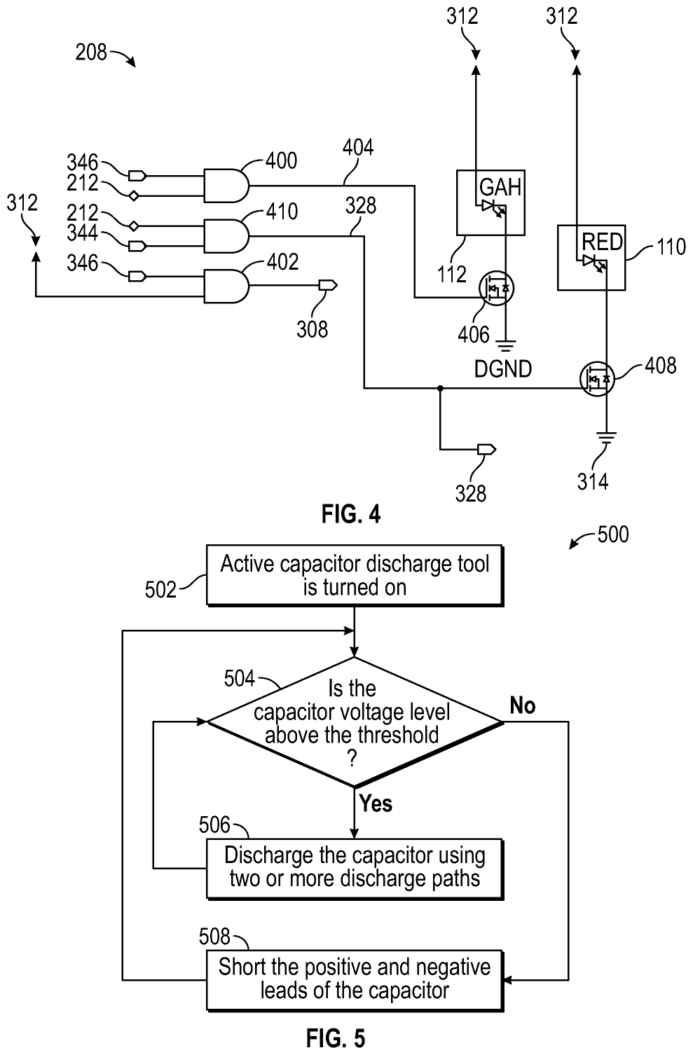

The first electrical path 300 and the second electrical path 302 may connect to a rectifier 304 and a relay switch 306. As mentioned above, the logic circuit 206 may monitor the voltage level of the capacitor 102. When the capacitor voltage level is below the threshold (e.g., below the sufficiently discharged voltage threshold, below 5V, 4V, 3V, 2.5V, 2.2V, 2.0V, 1.8V, 1.6V, 1.4V, 1.2V, 1.0V, etc.) or is discharged to a voltage below the threshold, the logic circuit 206 may transmit a first activation signal 308 to short the leads of the capacitor 102. A portion of the logic circuit 206 transmitting the first activation signal 308 is described below with respect to FIG. 4 (not shown in FIG. 3).

In the depicted embodiment, the first activation signal 308 may close a switch 310 (e.g., a FET). For example, the first activation signal 308 may charge a capacitor 309 to close the switch 310. In some cases, a resistor 311 may be disposed between the input of the switch 310 and a ground connection. The closed switch 310 may cause a current flow from a voltage source 312 (e.g., the battery 202, a regulated voltage source) through the switch 310 to the ground 314 connection. As such, the relay switch 306 may become energized. The energized relay switch 306 may short (e.g., connect) the first electrical path 300 and the second electrical path 302. Accordingly, the energized relay switch 306 may short the positive and negative leads of the capacitor 102 for discharging the capacitor 102 to reduce the capacitor voltage level to the ground voltage level (e.g., 0V, near 0V, 0.2V, 0.4V, 0.5V, 0.8V, 1.1V, 1.4V, etc.). Moreover, in different embodiments, the ground 314 connection may include an analog ground connection or digital ground connection with a voltage of 0V or near 0V.

That said, when the capacitor voltage level is above the threshold, the logic circuit 206 may discharge the capacitor 102 using two or more discharge paths through the rectifier 304. In the depicted embodiment, the logic circuit 206 may remove (e.g., set to low voltage) the first activation signal 308 when the capacitor voltage level is above the threshold. Accordingly, the switch 310 may open and the relay switch 306 may disconnect (e.g., open) the first electrical path 300 from the second electrical path 302.

As such, a first dispatch path 316 and a second dispatch path 318 may discharge the capacitor 102 through the rectifier 304, respective resistors 320 and 322, and respective switches 324 and 326. Discharging the capacitor 102 by actively switching between the multiple discharge paths may distribute a heat generated from discharging the capacitor 102 while discharging the capacitor at a faster rate. Accordingly, based on discharging the capacitor 102 using the first dispatch path 316 and the second dispatch path 318, a probability of overheating the capacitor 102 may be reduced and the capacitor 102 may discharge faster.

The first dispatch path 316 and the second dispatch path 318 may close to discharge the capacitor 102 based on a second activation signal 328. The logic circuit 206 may provide the second activation signal 328 to the first dispatch path 316 and the second dispatch path 318 based on detecting a capacitor voltage level higher than the threshold. The logic circuit 206 may provide the second activation signal 328 based on the clock signal 212 and using the clock frequency. Based on the clock frequency, the first dispatch path 316 and the second dispatch path 318 may alternatively close to discharge the capacitor 102.

In some cases, the switch 324 may close to discharge the capacitor 102 when the second activation signal 328 is high and the switch 326 may close to discharge the capacitor 102 when the second activation signal 328 is low. For example, an inverting circuit 330 may use switches 332 and 334 to invert the second activation signal 328. Moreover, the inverting circuit 330 may provide the inverted second activation signal 328 to the switch 326 of the second dispatch path 318. Accordingly, the discharge circuit 208 may distribute a heat generated based on discharging the capacitor 102 using the first dispatch path 316 and the second dispatch path 318.

That said, in alternative or additional cases, the discharge circuit 208 may include additional discharge paths (e.g., third discharge path, fourth discharge path, etc.). In such cases, the logic circuit 206 may also provide the second activation signal 328 to the additional discharge paths. For example, the discharge circuit 208 may include additional inverting circuits associated with the additional discharge paths. Additionally or alternatively, the discharge circuit 208 may include a different control scheme for distributing the clock signal 212 between the first dispatch path 316, the second dispatch path 318, and the additional discharge paths. For example, the different control scheme may distribute the clock signal 212 in any viable form to distribute a heat generated from discharging the capacitor 102 and discharge the capacitor 102 at a faster rate.

In any case, the logic circuit 206 may include a voltage comparator 336 for providing a high voltage indication signal 344 and a discharge complete indication signal 346. The voltage source 312 may provide the regulated voltage signal 210 to the voltage comparator 336. The voltage comparator 336 may monitor a voltage of a node 338. The node 338 may be positioned between a resistor 340 and a diode 342 to resist current flow to the ground 314. Accordingly, the voltage of the node 338 may correspond to a voltage of the first dispatch path 316 and the second dispatch path 318.

The voltage comparator 336 may provide the high voltage indication signal 344 when the voltage of the node 338 is above a threshold (e.g., 0.4V) corresponding to the sufficiently discharged capacitor voltage level threshold. Moreover, the voltage comparator 336 may provide the discharge complete indication signal 346 when the voltage of the node 338 is equal to or below the threshold. In some embodiments, the voltage of the node 338 may be lower than the capacitor voltage level based on a voltage drop across the rectifier 304. Accordingly, the voltage comparator 336 may provide the high voltage indication signal 344 and the discharge complete indication signal 346 based on a threshold (e.g., 0.4V) lower than a sufficiently discharged capacitor voltage level threshold to prevent electrical damage due to excessive charge (e.g., 1.8V).

FIG. 4 depicts another portion of the logic circuit 206 providing the first activation signal 308 and the second activation signal 328. The logic circuit 206 may include logic components to provide the first activation signal 308 and the second activation signal 328 based on receiving the high voltage indication signal 344 and/or the discharge complete indication signal 346. In some cases, the first activation signal 308 and the second activation signal 328 may correspond to the activation signals 214 described above with respect to FIG. 2.

In any case, a logic gate 400 and a logic gate 402 may receive the discharge complete indication signal 346 when the voltage of the node 338 is below the threshold (e.g., capacitor voltage level is low enough to enable an operator to handle the capacitor). In some cases, the logic gate 400 and the logic gate 402 may include an AND gate. In some embodiments, the logic gate 400 may also receive the clock signal 212 from the timer circuit 204. Accordingly, when the voltage of the node 338 is below the threshold, the logic gate 400 may provide a logic output 404 oscillating at the clock frequency. That said, in alternative or additional embodiments, the logic gate 400 may receive the regulated voltage signal 210 from the battery 202 in lieu of the clock signal 212. In such embodiments, the logic gate 400 may provide a high logic output 404.

A switch 406 (e.g., FET) may receive the logic output 404 from the logic gate 400. The switch 406 may close a connection to cause a current flow from the voltage source 312 through the complete LED indicator 112 and the switch 406 to the ground 314 connection. As mentioned above, the complete LED indicator 112 may provide a visual indication to an operator that the capacitor voltage level is below a threshold (e.g., sufficiently discharged voltage level). When the logic output 404 is oscillating based on the clock frequency, the switch 406 may open and close at a rate of the clock frequency. However, when the logic output 404 is high, the switch 406 may remain close. In one example, the complete LED indicator 112 may provide a green visual indication to the operator.

The logic gate 402 may receive the discharge complete indication signal 346 and the regulated voltage signal 210 from the voltage source 312 (e.g., the battery 202). The logic gate 402 may provide the first activation signal 308 in response to receiving the discharge complete indication signal 346 indicative of the capacitor voltage level is below the sufficiently discharged voltage threshold. As described above, the first activation signal 308 may cause shorting (e.g., connecting) the positive and negative leads of the capacitor 102 to discharge the capacitor 102 to the ground 314 voltage.

A logic gate 410 may receive the high voltage indication signal 344. In some cases, the logic gate 410 may also include an AND gate. In some embodiments, the logic gate 410 may also receive the clock signal 212 from the timer circuit 204. Accordingly, when the voltage of the node 338 is above the threshold (or the capacitor voltage level is higher than the sufficiently discharged voltage threshold), the logic gate 410 may provide the second activation signal 328 oscillating at the clock frequency. As such, as described above, the discharge circuit 208 may use the second activation signal 328 with the first dispatch path 316, the inverting circuit 330, and the second dispatch path 318 to discharge the capacitor 102. That is, the discharge circuit 208 may use the second activation signal 328 to discharge the capacitor using two or more discharge paths. Accordingly, the discharge circuit 208 may distribute a heat generated from discharging the capacitor 102 while discharging the capacitor 102 at a faster rate.

A switch 408 (e.g., FET) may receive the second activation signal 328 from the logic gate 410. The switch 408 may close a connection to cause a current flow from the voltage source 312 through the discharge led indicator 110 and the switch 408 to the ground 314. As mentioned above, the discharge led indicator 110 may provide a visual indication to the operator that the capacitor voltage level is above a threshold (e.g., high voltage level, unsafe voltage level). When the second activation signal 328 is oscillating based on the clock frequency, the switch 408 may open and close at a rate of the clock frequency. In one example, the discharge led indicator 110 may provide a red visual indication.

The logic circuit 206 may also include additional circuitry for providing the low battery indication via the low battery LED indicator 114 (not shown in FIG. 4). For example, the logic circuit 206 may include one or more additional voltage comparators and/or additional circuitry to provide the low battery visual indication (e.g., yellow visual indication) in response to detecting a lower than a threshold battery voltage level.

With the foregoing in mind, it should be appreciated that in alternative or additional embodiments, the logic circuit 206 and/or the discharge circuit 208 may include additional or alternative circuitry. That is, the logic circuit 206 and/or the discharge circuit 208 may include any viable circuitry to discharge the capacitor using two or more discharge paths, distribute a heat generated from discharging the capacitor 102, and/or discharge the capacitor 102 at a faster rate. Moreover, in alternative or additional cases, the active capacitor discharge tool 100 may include different protective circuitry such as voltage spike mitigation circuitry, current spike mitigation circuitry, and/or fuse circuitry. Furthermore, the active capacitor discharge tool 100 may include multiple voltage regulators and/or voltage sources to provide different voltage levels to different parts of the logic circuit 206 and/or the discharge circuit 208.

With the foregoing in mind, FIG. 5 describes an operating process 500 associated with the active capacitor discharge tool 100. Although the operating process 500 is described in a particular order, it should be appreciated the active capacitor discharge tool 100 may perform the process blocks of the operating process 500 in a different order. Moreover, in alternative or additional embodiments, the operating process 500 may include additional or less process blocks.

At block 502, the active capacitor discharge tool 100 may be turned on. For example, an operator may connect the positive and negative leads of the capacitor 102 to the active capacitor discharge tool 100. In one embodiment, the operator may turn on the active capacitor discharge tool 100 using the power switch 108. In another embodiment, the operator may use a different kind of switching circuitry to turn on the active capacitor discharge tool 100. In yet another embodiment, the active capacitor discharge tool 100 may include circuitry to automatically turn on, for example, based on connecting to the capacitor 102, a high capacitor voltage level, among other things.

At block 504, the active capacitor discharge tool 100 may determine whether the capacitor voltage level is above the threshold. As mentioned above, the threshold may correspond to a sufficiently discharged voltage threshold associated with the capacitor 102. For example, when an operator is in close proximity of the capacitor 102, a capacitor voltage level above the threshold may electrically shock and/or burn the operator.

When the capacitor voltage level is above the threshold, at block 506, the active capacitor discharge tool 100 may discharge the capacitor 102 using two or more discharge paths. An embodiment associated with discharging the capacitor 102 using two discharge paths is described above with respect to FIGS. 3 and 4. That said, in alternative or additional embodiments, the active capacitor discharge tool 100 may discharge the capacitor 102 using more than two discharge paths. Accordingly, the active capacitor discharge tool 100 may discharge the capacitor 102 at a faster rate while distributing a heat generated from the discharging.

Moreover, at block 506, the active capacitor discharge tool 100 may return to block 504 to determine whether the capacitor voltage level is above the threshold. In different embodiments, while discharging the capacitor 102 at block 506, the active capacitor discharge tool 100 may return to block 504 continuously, periodically, or based on a triggering event (e.g., a timer, a charge sensing component triggering signal, etc.) to determine whether the capacitor voltage level is above the threshold. In any case, when the capacitor voltage level is equal to or below the threshold, the active capacitor discharge tool 100 may proceed to operations of block 508

At block 508, the active capacitor discharge tool 100 may short the positive and negative leads of the capacitor 102. Accordingly, the active capacitor discharge tool 100 may discharge the voltage/charge level to lower voltage/charge levels based on shorting the capacitor 102 leads. In some cases, the capacitor 102 may discharge to 0V, near 0V, or ground voltage (e.g., voltage level of the ground 314 reference voltage).

That said, at block 508, the active capacitor discharge tool 100 may continuously or periodically return to block 504. That is, the active capacitor discharge tool 100 mat continuously or periodically determine whether the capacitor voltage level is above the threshold at block 504. In any case, the active capacitor discharge tool 100 may discharge the capacitor 102 at a fast rate, with distributed discharging heat that may allow fast heat dissipation, and to a low voltage level (e.g., 0V, near 0V, or ground voltage) based on the operating process 500.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure. Moreover, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An electronic device, comprising:
a connector configured to couple to an electrical component, wherein the electrical component is configured to hold an electrical charge;
a timer circuit configured to provide a clock signal oscillating at a clock frequency;
a logic circuit configured to determine whether a voltage associated with the electrical component is higher than a threshold when the connector is coupled to the electrical component; and
a discharge circuit comprising at least a first discharge path and a second discharge path operating according to the clock signal, wherein the discharge circuit is configured to discharge the electrical component by alternatively closing the first discharge path and the second discharge path based on the clock frequency in response to the logic circuit determining that the voltage is higher than the threshold.

2. The electronic device of claim 1, comprising a voltage source configured to provide electric power to the timer circuit, the logic circuit, and the discharge circuit.

3. The electronic device of claim 1, wherein the electrical component comprises a capacitor and the threshold corresponds to a sufficiently low discharged voltage to enable an operator associated with the capacitor to handle the capacitor.

4. The electronic device of claim 1, wherein the logic circuit is configured to provide a high voltage indication signal to the discharge circuit in response to the voltage associated with the electrical component being higher than the threshold.

5. The electronic device of claim 4, wherein the discharge circuit is configured to discharge the electrical component by alternatively closing the first discharge path and the second discharge path based on the clock frequency in response to receiving the high voltage indication signal.

6. The electronic device of claim 1, wherein the discharge circuit is configured to discharge the electrical component by the first discharge path, the second discharge path, or both, in response to the logic circuit determining that the voltage is higher than the threshold.

7. The electronic device of claim 6, wherein discharging the electrical component by the first discharge path and the second discharge path is based on an overlapping period when alternatively closing the first discharge path and the second discharge path based on the clock frequency.

8. The electronic device of claim 1, wherein the logic circuit is configured to provide a discharge complete indication signal to the discharge circuit in response to the voltage associated with the electrical component being equal to or below the threshold.

9. The electronic device of claim 8, wherein the discharge circuit is configured to short a positive and a negative lead of the electrical component in response to receiving the discharge complete indication signal.

10. The electronic device of claim 1, wherein alternatively closing the first discharge path and the second discharge path based on the clock frequency comprises:
closing the first discharge path and opening the second discharge path in response to a high voltage pulse of the clock signal; and
closing the second discharge path and opening the first discharge path in response to a low voltage pulse of the clock signal.

11. The electronic device of claim 10, wherein the logic circuit comprises inverter circuitry, and wherein closing the second discharge path in response to a low pulse of the clock signal is based on the second discharge path receiving an inverted clock signal from the inverter circuitry.

12. A method, comprising:
determining, by an active capacitor discharge tool connected to a capacitor, that a voltage associated with the capacitor is above a threshold;
discharging, by the capacitor discharge tool, electrical charge associated with the capacitor by alternatively shorting the capacitor to ground using at least a first discharge path and a second discharge path based on a clock frequency of a clock signal of the active capacitor discharge tool;
determining, by the capacitor discharge tool, that the voltage associated with the capacitor is equal to or below the threshold based on discharging the capacitor using the at least two discharging paths; and
discharging, by the active capacitor discharge tool, electrical charges associated with the capacitor by shorting a positive lead and a negative lead of the capacitor.

13. The method of claim 12, comprising turning on the active capacitor discharge tool for:
actively determining that the voltage associated with the capacitor is above the threshold or is equal to or below the threshold based on using active comparator circuitry;
actively discharging the electrical charges associated with the capacitor by alternatively shorting the capacitor to ground using at least the first discharge path and the second discharge path using active switching components and active inverter circuitry; and
actively discharging the electrical charges associated with the capacitor by shorting the positive lead and the negative lead of the capacitor using an active relay switch.

14. The method of claim 12, wherein alternatively shorting the capacitor is based on:
grounding the capacitor using the first discharge path in response to receiving a high voltage pulse of the clock signal; and
grounding the capacitor using the second discharge path in response to receiving a low voltage pulse of the clock signal.

15. The method of claim 12, wherein:
the threshold corresponds to a sufficiently discharged voltage for an operator associated with the capacitor; and
the voltage associated with the capacitor is determined based on sensing a voltage of an internal node of the active capacitor discharge tool.

16. The method of claim 12, wherein shorting the positive lead and the negative lead of the capacitor discharges the capacitor to a ground voltage level associated with the active capacitor discharge tool.

17. A capacitor discharge tool, comprising:
a timer circuit configured to provide a clock signal;
a voltage comparator configured to:
provide a high voltage indicator signal in response to determining that a voltage associated with a capacitor is higher than a threshold; and
provide a sufficiently discharged voltage indicator signal in response to determining that the voltage associated with the capacitor is equal to or below the threshold;
a first discharge path configured to ground the capacitor in response to:
the voltage comparator providing the high voltage indicator signal; and
the timer circuit providing a high pulse of the clock signal; and
a second discharge path configured to ground the capacitor in response to:
the voltage comparator providing the high voltage indicator signal; and
the timer circuit providing a low pulse of the clock signal.

18. The capacitor discharge tool of claim 17, wherein the first discharge path comprises a switch, wherein the switch receives an activation signal based on the voltage comparator providing the high voltage indicator signal and the timer circuit providing the high pulse of the clock signal to short the first discharge path.

19. The capacitor discharge tool of claim 17, wherein the second discharge path comprises a switch and inverter circuitry, wherein the inverter circuitry is configured to provide an inverted activation signal to the switch based on receiving an activation signal based on the voltage comparator providing the high voltage indicator signal and the timer circuit providing the low pulse of the clock signal to short the second discharge path.

20. The capacitor discharge tool of claim 17, comprising:
a discharge LED indicator configured to provide an indication of high capacitor voltage in response to receiving the high voltage indicator signal; and
a sufficiently discharged LED indicator configured to provide an indication of sufficiently discharged capacitor voltage in response to receiving the sufficiently discharged voltage indicator signal.

21. The capacitor discharge tool of claim 17, comprising a relay switch configured to short a cathode and an anode of the capacitor in response to the voltage comparator providing the sufficiently discharged voltage indicator signal.

22. The capacitor discharge tool of claim 21, wherein the shorting a cathode and an anode of the capacitor discharges the capacitor to a ground voltage level associated with the capacitor discharge tool.
